(19) United States
(12) Patent Application Publication
(10) Pub. No.: US 2004/0189399 A1
(43) Pub. Date: Sep. 30, 2004

(54) Bias circuit for a radio frequency power amplifier

(76) Inventors: Cheng-chi Hu, Tainan (TW); Janne-wha Wu, Chiai (TW); Ying-chou Shih, Tainan (TW)

Correspondence Address: MARTINE & PENILLA, LLP, 710 LAKEWAY DRIVE, SUITE 170, SUNNYVALE, CA, 94085, US

(21) Appl. No.: 10/817,600

(22) Filed: Apr. 2, 2004

Related U.S. Application Data
(62) Division of application No. 10/355,665, filed on Jan. 31, 2003.

(30) Foreign Application Priority Data
Dec. 17, 2002 (TW) 91136460

(51) Int. Cl. H03F 3/04

(52) U.S. Cl. 330/296

(57) ABSTRACT

A bias circuit for a radio frequency power amplifier includes a bias transistor having a collector, an emitter, and a base, wherein the collector is connected to a DC voltage source, the emitter is connected to a radio frequency transistor, and the base is connected to a bias voltage source. An inductor is connected between the base of the radio frequency transistor and the emitter of the bias transistor, for blocking part of a radio frequency input signal coupled back to the bias transistor. A capacitor is connected between the base of the bias transistor and ground, for directly conducting the part of the radio frequency input signal coupled back to the bias transistor, into the ground, thereby preventing the bias transistor from being driven into a saturation state.

### CROSS REFERENCE TO RELATED APPLICATIONS

This application is a divisional patent application, which claims priority under 35 U.S.C. § 120 of U.S. patent application Ser. No. 10/355,665, filed on Jan. 31, 2003, and which is incorporated by reference herein.

### BACKGROUND OF THE INVENTION

1. Field of the Invention

The present invention relates to a bias circuit for a radio frequency power amplifier and, more particularly, to a bias circuit capable of improving linearity of a radio frequency power amplifier.

2. Description of the Related Art

FIG. 1 is a schematic diagram showing an example of a conventional bias circuit for a radio frequency (RF) power amplifier. Referring to FIG. 1, in a conventional resistive bias circuit 100, a bias voltage source Vbias is supplied to a base of an RF transistor 102 through a bias resistor 104, thereby providing a base current of the RF transistor 102. A capacitor 106 is connected between an RF input port of the RF power amplifier and the base of the RF transistor 102, thereby coupling an RF input signal (but not a direct-current signal) to the base of the RF transistor 102. Through an output matching circuit 108, a collector of the RF transistor 102 serves an output port of the RF power amplifier. The conventional resistive bias circuit 100 has a disadvantage of providing a limit control over the bias current. For example, if the bias resistor 104 has a small resistance, temperature variations will cause unacceptable fluctuations in the quiescent current unless the bias voltage source Vbias also changes with temperature. On the other hand, if the bias resistor 104 has a large resistance, the RF transistor 102 will have insufficient bias current at high drive levels or have a large quiescent bias current which is undesirable.

FIG. 2 is a schematic diagram showing another example of a conventional bias circuit for an RF power amplifier. A conventional active bias circuit 200 shown in FIG. 2 is an improvement of the conventional resistive bias circuit 100 shown in FIG. 1. Referring to FIG. 2, the conventional active bias circuit 200 includes a bias transistor 202 for allowing the RF transistor 102 to draw varying amounts of bias current depending on the RF drive level while still maintaining a low quiescent current level. The bias voltage source Vbias is supplied to a base of the bias transistor 202 through the bias resistor 104. The bias transistor 202 is an emitter-follower-type transistor. A collector of the bias transistor 202 is connected to a DC voltage Vcc. The conventional active bias circuit 200 further has an advantage of low impedance.

However, the active bias circuit 200 shown in FIG. 2 has a disadvantage that the bias transistor 202 may be driven into a saturation state. More specifically, when the RF transistor 102 are driven to output a high power, part of the RF input signal is reflected from the collector of the RF transistor 102 back to the base of the RF transistor 102, and may further enter the active bias circuit 200. As a result, the bias transistor 202 is driven into the saturation state by the part of the RF input signal coupled back to the bias transistor 202, causing its operation to become more nonlinear. Under this circumstance, the active bias circuit 200 cannot follow the RF input signal to provide the RF transistor 102 with a linear bias current.

### SUMMARY OF THE INVENTION

In view of the above-mentioned problem, an object of the present invention is to provide a bias circuit for an RF power amplifier capable of preventing a bias transistor from being influenced by an RF input signal, thereby improving linearity of the RF power amplifier.

According to one aspect of the present invention, a bias circuit for an RF power amplifier is provided. The RF power amplifier includes an RF transistor and a first capacitor. The RF transistor has a collector, an emitter, and a base. The first capacitor has a terminal connected to the base of the RF transistor and another terminal for receiving an RF input signal. The bias circuit includes: a bias transistor having a collector, an emitter, and a base, the collector connected to a DC voltage source and the base connected to a bias voltage source, and a second capacitor connected between the base of the bias transistor and ground for directly conducting part of the RF input signal coupled to the bias transistor into the ground, thereby preventing the bias transistor from being driven into a saturation state.

According to still another aspect of the present invention, a bias circuit for an RF power amplifier further comprises an inductor connected between the base of the RF transistor and the emitter of the bias transistor for blocking part of the RF input signal coupled to the bias transistor.

### BRIEF DESCRIPTION OF THE DRAWINGS

The above-mentioned and other objects, features, and advantages of the present invention will become apparent with reference to the following descriptions and accompanying drawings, wherein:

FIG. 1 is a schematic diagram showing an example of a conventional bias circuit for an RF power amplifier;

FIG. 2 is a schematic diagram showing another example of a conventional bias circuit for an RF power amplifier; and

FIG. 3 are schematic diagrams showing preferred embodiments of a bias circuit for an RF power amplifier according to the present invention.

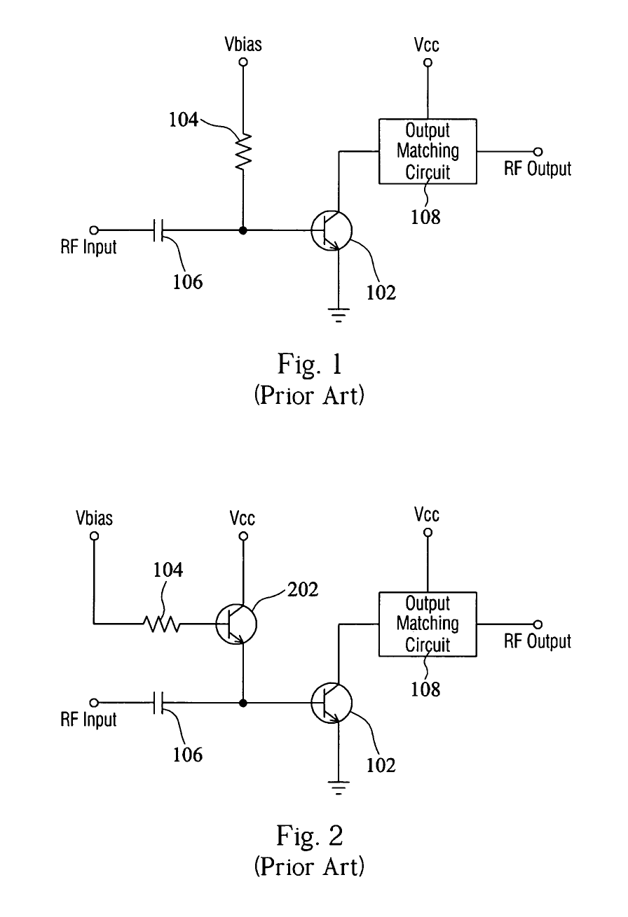

### DETAILED DESCRIPTION OF THE PREFERRED EMBODIMENTS

The preferred embodiments according to the present invention will be described in detail with reference to the drawings.

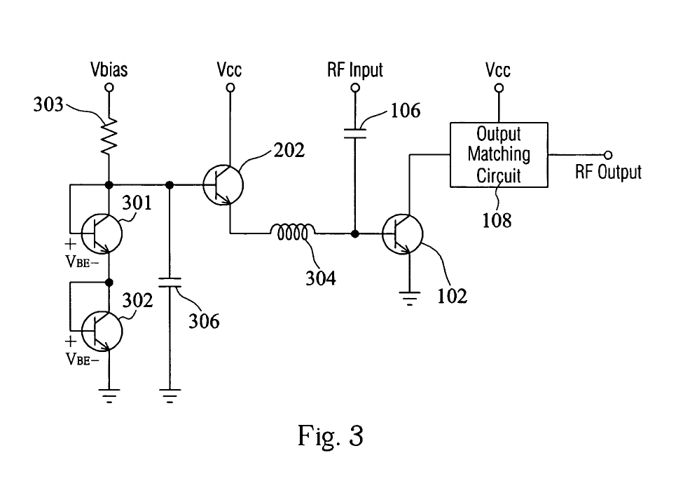

FIG. 3 is a schematic diagram showing one embodiment of a bias circuit for an RF power amplifier according to the present invention. Referring to FIG. 3, in the bias circuit for the RF power amplifier according to the present invention, a bias voltage source Vbias supplies current through a resistor 303 to diode-connected transistors 301 and 302 which are connected in series. More specifically, each of the diode-connected transistors 301 and 302 has a configuration that a base thereof is connected to a collector thereof and, therefore, operates as a diode. The voltage at the collector of the diode-connected transistor 301 is two times V_{BE}. This voltage is applied to the base of the bias transistor 202, the emitter-follower-type transistor. The collector of the bias transistor 202 is connected to the DC voltage source Vcc. Because the emitter voltage is the base voltage minus V_{BE}, the emitter voltage of the bias transistor 202 is equal to V_{BE}(2V_{BE} [symbol] V_{BE}=V_{BE}). This is the bias voltage applied to the RF transistor 102.

In order to prevent the RF input signal from coupling back to the bias transistor 202 to undesirably drive the bias transistor 202 into a saturation state, an inductor 304 is provided between the emitter of the bias transistor 202 and the base of the RF transistor 102. The inductor 304 blocks the part of the RF input signal coupled back to the bias transistor 202, thereby preventing the bias transistor 202 from being driven into the saturation state. Therefore, the linearity of the RF power amplifier is improved.

Although the inductor 304 effectively blocks the part of the RF input signal coupled back to the bias transistor 202, the block efficiency cannot be 100%. In view of this deficiency, the bias circuit for the RF power amplifier according to the present invention further includes a capacitor 306 connected between the base of the bias transistor 202 and ground. Since the capacitor 306 operates as if a short circuit with respect to the RF input signal, the part of the RF input signal coupled back to the bias transistor 202 is directly conducted into the ground. In this way, the bias transistor 202 is prevented from being driven by the RF input signal into the saturation state, thereby improving the linearity of the RF power amplifier.

While the invention has been described by way of examples and in terms of preferred embodiments, it is to be understood that the invention is not limited to the disclosed embodiments. To the contrary, it is intended to cover various modifications. Therefore, the scope of the appended claims should be accorded the broadest interpretation so as to encompass all such modifications.

What is claimed:

1. A bias circuit for an RF power amplifier, the RF power amplifier including an RF transistor and a first capacitor, the RF transistor having a collector, an emitter, and a base, the first capacitor having a terminal connected to the base of the RF transistor and another terminal for receiving an RF input signal, the bias circuit comprising:
a bias transistor having a collector, an emitter, and a base, the collector connected to a DC voltage source and the base connected to a bias voltage source; and
a second capacitor connected between the base of the bias transistor and ground for directly conducting part of the RF input signal coupled to the bias transistor into the ground, thereby preventing the bias transistor from being driven into a saturation state.

2. The bias circuit according to claim 1, further comprising
an inductor connected between the base of the RF transistor and the emitter of the bias transistor for blocking part of the RF input signal coupled to the bias transistor.

3. The bias circuit according to claim 1, wherein the bias voltage source comprises:
a resistor connected between the bias voltage source and the base of the bias transistor; and
a plurality of diodes connected in series between the base of the bias transistor and ground for providing a predetermined voltage to the base of the bias transistor.

4. The bias circuit according to claim 3, wherein
each of the plurality of diodes is formed by a transistor having a configuration that a base thereof is connected to a collector thereof.
